(19) United States
(12) Patent Application Publication
(10) Pub. No.: US 2021/0020408 A1
(43) Pub. Date: Jan. 21, 2021

(54) SUBSTRATE SUPPORT ASSEMBLY, SUBSTRATE PROCESSING APPARATUS, AND EDGE RING

(71) Applicant: Tokyo Electron Limited, Tokyo (JP)

(72) Inventors: Hideki SUGIYAMA, Miyagi (JP); Shunsuke KANEKO, Miyagi (JP); Akihiro OGASAWARA, Miyagi (JP)

(21) Appl. No.: 16/925,806

(22) Filed: Jul. 10, 2020

(30) Foreign Application Priority Data
Jul. 19, 2019 (JP) 2019-134077

(51) Int. Cl. H01J 37/32; H01L 21/3065; H01J 37/07; H01J 37/20

(52) U.S. Cl. CPC H01J 37/32082; H01J 37/20; H01J 37/07; H01L 21/3065

(57) ABSTRACT

There is provision of a substrate support assembly including an edge ring, a substrate support, and a thermal conductivity adjuster. The substrate support has a central portion that supports a substrate, and an outer peripheral portion that supports the edge ring arranged around the substrate. The thermal conductivity adjuster is in contact with a part of the edge ring in a circumferential direction, and a thermal conductivity of the thermal conductivity adjuster is different from a thermal conductivity of the edge ring.

### CROSS-REFERENCE TO RELATED APPLICATIONS

This patent application is based upon and claims priority to Japanese Patent Application No. 2019-134077 filed on Jul. 19, 2019, the entire contents of which are incorporated herein by reference.

### TECHNICAL FIELD

The present disclosure relates to a substrate support assembly, a substrate processing apparatus, and an edge ring.

### BACKGROUND

For example, Patent Document 1 describes a technique to generate constant electrostatic attractive force between an electrostatic chuck and a focus ring constant, and thus a degree of close contact between the electrostatic chuck and the focus ring can be made uniform. The focus ring described in Patent Document 1 includes a groove extending in a circumferential direction.

### RELATED ART DOCUMENT

### Patent Document

[Patent Document 1] Japanese Laid-open Patent Application Publication No. 2005-064460

### SUMMARY

The present disclosure provides a technique for improving uniformity in temperature of the edge ring.

According to one aspect of the present disclosure, there is provision of a substrate support assembly including an edge ring, a substrate support, and a thermal conductivity adjuster. The substrate support has a central portion that supports a substrate, and an outer peripheral portion that supports the edge ring arranged around the substrate. The thermal conductivity adjuster is in contact with a part of the edge ring in a circumferential direction, and a thermal conductivity of the thermal conductivity adjuster is different from a thermal conductivity of the edge ring.

### BRIEF DESCRIPTION OF THE DRAWINGS

FIG. 1 illustrates a substrate processing apparatus including a mounting table assembly according to an embodiment;

FIG. 2 is a diagram illustrating heat transfer of an edge ring according to the embodiment;

FIG. 3 is a back view of the edge ring according to the embodiment;

FIG. 4 is a diagram illustrating an example of a first variation of the edge ring according to the embodiment;

FIG. 5 is a diagram illustrating an example of a second variation of the edge ring according to the embodiment;

FIG. 6 is a diagram illustrating an example of a third variation of the edge ring according to the embodiment;

FIG. 7 is a diagram illustrating an example of a fourth variation of the edge ring according to the embodiment;

FIG. 8 is a diagram illustrating an example of a fifth variation of the edge ring according to the embodiment;

FIG. 9 is a diagram illustrating an example of a sixth variation of the edge ring according to the embodiment;

FIG. 10 is a diagram illustrating an example of a seventh variation of the edge ring according to the embodiment;

FIG. 11 is a diagram illustrating an example of a first variation of the mounting table assembly according to the embodiment;

FIG. 12 is a diagram illustrating an example of a second variation of the mounting table assembly according to the embodiment; and

FIG. 13 is a back view of an example of an edge ring according to a comparative example.

### DETAILED DESCRIPTION OF EMBODIMENTS

Hereinafter, embodiments for carrying out the present disclosure will be described with reference to the drawings. Note that in the present specification and drawings, elements having substantially identical features are given the same reference symbols, and redundant descriptions will be omitted.

### <Overall Configuration of Substrate Processing Apparatus>

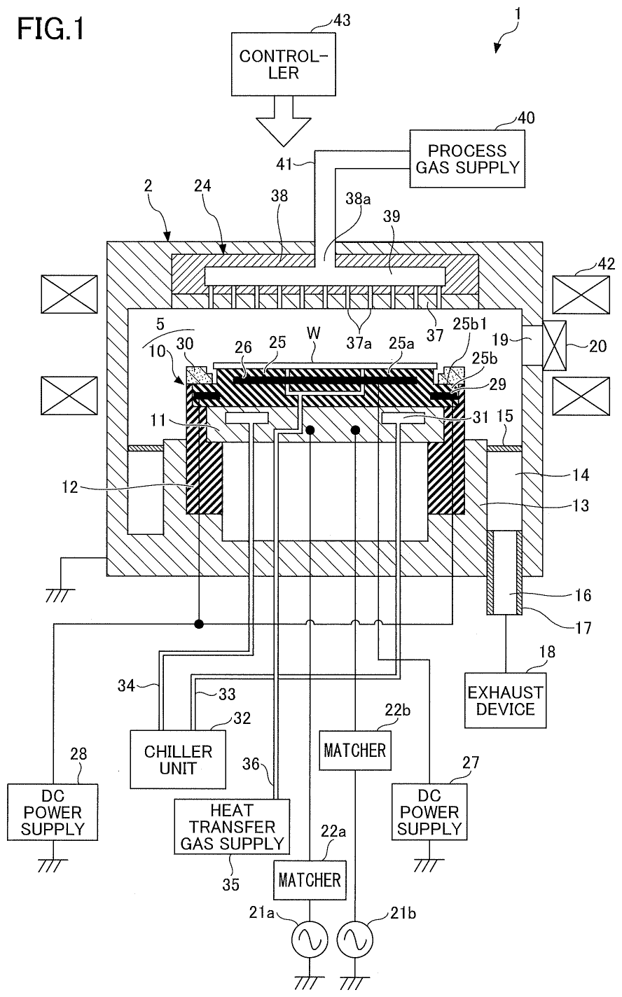

First, an example of the overall configuration of a substrate processing apparatus 1 will be described with reference to FIG. 1. FIG. 1 is a cross-sectional view illustrating the schematic configuration of the substrate processing apparatus 1 according to the present embodiment. In the present embodiment, a case in which the substrate processing apparatus 1 is an RIE (Reactive Ion Etching) type substrate processing apparatus will be described. However, the substrate processing apparatus 1 may be a plasma etching apparatus or a plasma CVD (Chemical Vapor Deposition) apparatus.

In FIG. 1, the substrate processing apparatus 1 includes a cylindrical processing vessel 2 made of metal such as aluminum or stainless steel. The processing vessel 2 is electrically grounded, and a disc-shaped mounting table 10 on which a substrate W is placed is provided within the processing vessel 2. The mounting table 10 may also be referred to as a “substrate support 10”. The mounting table 10 includes a base 11 and an electrostatic chuck 25. The combination of the mounting table 10 and an edge ring 30 is referred to as a “mounting table assembly 5” or a “substrate support assembly 5”. The edge ring 30 may also be referred to as a focus ring. The base 11 functions as a bottom electrode. The base 11 is, for example, made of aluminum, and is supported by a cylindrical support 13 which extends vertically upward from the bottom of the processing vessel 2, via a cylindrical insulating retainer 12.

An exhaust passage 14 is formed between the inner side wall of the processing vessel 2 and the outer side wall of the cylindrical support 13, and an annular baffle plate 15 is disposed at the inlet or midway of the exhaust passage 14. Also, an exhaust port 16 is disposed at the bottom of the exhaust passage 14, and an exhaust device 18 is connected to the exhaust port 16 via an exhaust pipe 17. Here, the exhaust device 18 includes a dry pump and a vacuum pump to reduce the pressure in a processing space of the processing vessel 2 to a predetermined level. The exhaust pipe 17 also includes an automatic pressure control valve (hereinafter referred to as “APC”) which is a variable butterfly valve, and the APC automatically controls the pressure in the processing vessel 2. Further, a gate valve 20 for opening and closing a loading/unloading port 19 for the substrate W is attached to the side wall of the processing vessel 2.

A first radio frequency power supply 21a is connected to the base 11 via a first matcher 22a. A second radio frequency power supply 21b is connected to the base 11 through a second matcher 22b. The first radio frequency power supply 21a supplies, to the base 11, radio frequency electric power at a first predetermined frequency (e.g., 100 MHz) for plasma generation. The second radio frequency power supply 21b supplies radio frequency electric power for ion retraction to the base 11, at a second predetermined frequency lower than the first predetermined frequency (e.g., 13 MHz).

A showerhead 24, which also functions as an upper electrode, is disposed at the ceiling of the processing vessel 2. This causes two types of high frequency voltage to be applied between the base 11 and the showerhead 24, from the first and second radio frequency power supplies 21a and 21b.

The electrostatic chuck 25 is provided on the upper surface of the base 11 to attract the substrate W by electrostatic attractive force. The electrostatic chuck 25 includes a disc-like central portion 25a on which the substrate W is placed, and an annular peripheral portion 25b which is formed to surround the central portion 25a. The central portion 25a protrudes upward in the drawing, with respect to the peripheral portion 25b. On a mounting surface 25b1 of the peripheral portion 25b, the annular edge ring 30 that surrounds the central portion 25a is mounted. Also, the central portion 25a is formed by inserting an electrode plate 26 made of a conductive film between a pair of dielectric films.

The peripheral portion 25b is formed by inserting an electrode plate 29 made of a conductive film between a pair of dielectric films. A direct-current (DC) power supply 27 is electrically connected to the electrode plate 26. The DC power supply 27 and a DC power supply 28 are capable of changing magnitude and polarity of DC voltage supplied. The DC power supply 27 applies DC voltage to the electrode plate 26 under the control of a controller 43, which will be described below. The DC power supply 28 applies DC voltage to the electrode plate 29 under the control of the controller 43. As voltage is applied to the electrode plate 26 from the DC power supply 27, the electrostatic chuck 25 generates electrostatic force, i.e., Coulomb force, and the substrate W is attracted and held to the electrostatic chuck 25 by the electrostatic force. The electrostatic chuck 25 also generates electrostatic force, i.e., Coulomb force, by voltage applied to the electrode plate 29 from the DC power supply 28, and the edge ring 30 is attracted and held to the electrostatic chuck 25 by the electrostatic force. Note that the mounting table 10 may not include the electrostatic chuck 25.

Inside the base 11 is an annular refrigerant chamber 31 that extends circumferentially, for example. A chiller unit 32 supplies a refrigerant at a predetermined temperature, such as cooling water, to the refrigerant chamber 31 in a circulating manner through pipes 33 and 34, and a processing temperature of the substrate W on the electrostatic chuck 25 is controlled by the refrigerant. The refrigerant is a temperature adjusting medium that circulates in the refrigerant chamber 31 via the pipes 33 and 34. The temperature adjusting medium not only cools the base 11 and the substrate W, but may also heat them.

A heat transfer gas supply 35 is connected to the electrostatic chuck 25 via a gas supply line 36. The heat transfer gas supply 35 supplies a heat transfer gas to a space between the central portion 25a of the electrostatic chuck 25 and the substrate W, through the gas supply line 36. As the heat transfer gas, a heat conductive gas, such as He gas, is preferably used.

The showerhead 24 at the ceiling includes an electrode plate 37 having a large number of gas holes 37a and an electrode support 38 detachably supporting the electrode plate 37. The electrode plate 37 is provided at the bottom surface of the electrode support 38. A buffer chamber 39 is provided within the electrode support 38, and a gas inlet 38a is provided at the upper surface of the buffer chamber 39. A process gas supply 40 is connected to the gas inlet 38a via a gas supply line 41. An annular magnet 42 is disposed coaxially around the processing vessel 2.

Each component of the substrate processing apparatus 1 is coupled to the controller 43. For example, the exhaust device 18, the first radio frequency power supply 21a, the second radio frequency power supply 21b, the DC power supply 27, the DC power supply 28, the chiller unit 32, the heat transfer gas supply 35, and the process gas supply 40 are coupled to the controller 43. The controller 43 controls each of the components of the substrate processing apparatus 1.

The controller 43 includes a central processing unit (CPU) and a storage device such as a memory, which are not illustrated. The controller 43 causes the substrate processing apparatus 1 to perform desired processes, by the CPU reading out and executing a program and a process recipe stored in the storage device. For example, an electrostatic attracting process for attracting the edge ring 30 electrostatically is performed in the substrate processing apparatus 1, by the controller 43.

In the processing vessel 2 of the substrate processing apparatus 1, a horizontal magnetic field directed in a single direction is formed by the magnet 42, and a radio frequency (RF) electric field is formed in a vertical direction by radio frequency voltage applied between the base 11 and the showerhead 24. This causes magnetron discharge through a process gas in the processing vessel 2, and a plasma is formed from the process gas near the surface of the base 11.

In the substrate processing apparatus 1, when performing dry etching, the gate valve 20 is first opened, and a substrate W to be processed is loaded into the processing vessel 2 and placed on the electrostatic chuck 25. Subsequently, in the substrate processing apparatus 1, a process gas (for example, a mixture of C₄F₈ gas, O₂ gas, and Ar gas) is introduced into the processing vessel 2 at a predetermined flow rate and flow rate ratio from the process gas supply 40, and the pressure in the processing vessel 2 is set to a predetermined value by the exhaust device 18 and the like.

Next, in the substrate processing apparatus 1, different types of radio frequency electric power each having a different frequency are supplied to the base 11 from the first radio frequency power supply 21a and the second radio frequency power supply 21b, respectively. Also, in the substrate processing apparatus 1, DC voltage is applied to the electrode plate 26 of the electrostatic chuck 25 from the DC power supply 27 to attract the substrate W to the electrostatic chuck 25. Further, in the substrate processing apparatus 1, DC voltage is applied from the DC power supply 28 to the electrode plate 29 of the electrostatic chuck 25 to attract the edge ring 30 to the electrostatic chuck 25. The process gas discharged from the showerhead 24 is formed into a plasma, and etching treatment is applied to the substrate W by radicals and ions in the plasma.

### <Edge Ring>

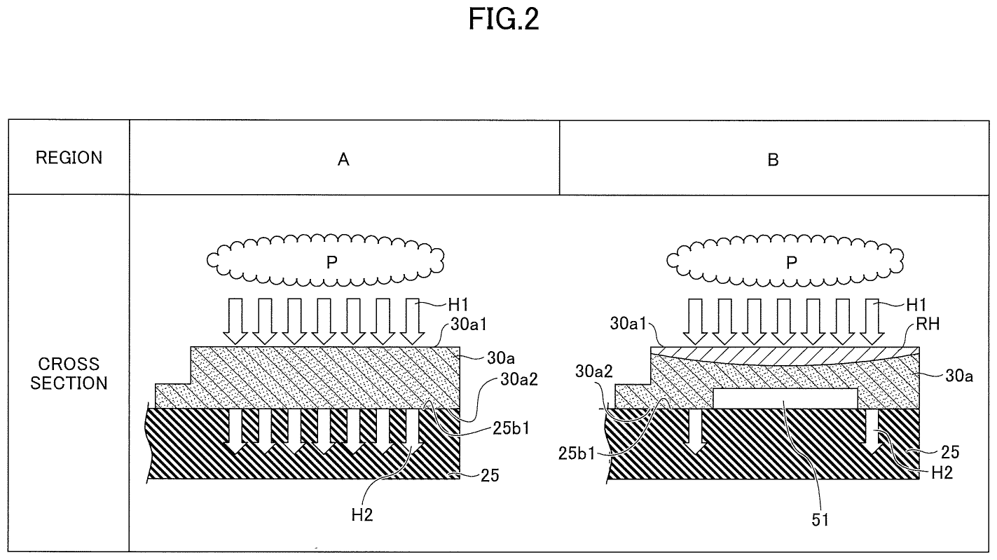

Next, the edge ring 30 of the present embodiment will be described with reference to FIG. 2. FIG. 2 is a diagram illustrating heat transfer of the edge ring 30 according to the present embodiment.

### [Edge Ring Temperature Distribution]

In the substrate processing apparatus 1, when a plasma P is generated during plasma processing, the substrate W and the edge ring 30 are heated by heat from the plasma P. Heat of the edge ring 30 is removed through the mounting table 10 by a material on the mounting table 10 or by a cooling mechanism provided in the mounting table 10.

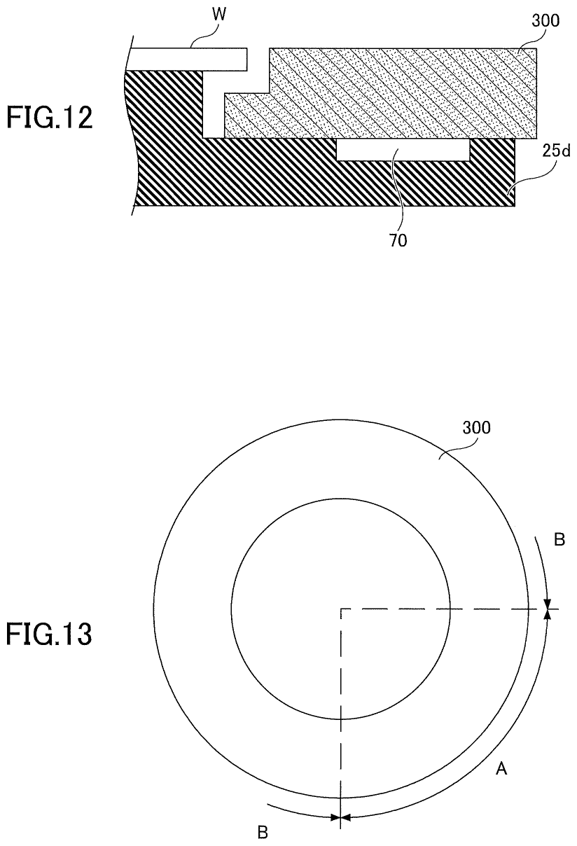

First, as a comparative example, a case in which a flat edge ring 300 not having grooves on the back surface of the edge ring 300 is mounted on the mounting surface 25b1 of the electrostatic chuck 25 will be described. FIG. 13 is a diagram illustrating the back surface of the edge ring 300 according to the comparative example. When a plasma process is applied to the substrate processing apparatus 1, the temperature of the edge ring 300 may become uneven depending on locations due to the internal structure of the mounting table 10 or the like. Causes of uneven temperature may be, for example, a voltage terminal of the electrostatic chuck 25; a heater terminal; locations of an inlet, outlets, and the like, of a chiller flow passage; a layout of a heater electrode; a layout of the chiller flow passage; and temperature gradient in the chiller flow passage. As a result of such causes of the uneven temperature, in a case in which the edge ring 300 is used, a temperature difference (temperature distribution) of approximately 5° C. may occur in the edge ring 300 in the circumferential direction.

Accordingly, in the substrate processing apparatus 1 of the present embodiment, with respect to a region in which the temperature of the edge ring 30 is relatively low, the edge ring 30 is configured such that heat transfer efficiency between the region of the edge ring 30 and the electrostatic chuck 25 is relatively low. Specifically, the back surface of the edge ring 30 is provided with a portion having low heat transfer efficiency between the mounting surface 25b1 and the mounting surface 25b1. As such, if the heat transfer efficiency is low in the region in which the temperature of the edge ring 30 is low, the temperature of the region of the edge ring 30 is higher in comparison to the edge ring 300, because heat is not easily removed via the mounting table 10. That is, the edge ring 30 is formed such that the heat transfer efficiency between the edge ring 30 and the electrostatic chuck 25 is non-uniform to produce a temperature distribution. Thus, by degrading the heat transfer efficiency of the region in which the temperature of the edge ring 30 is low, temperature of the mounting table assembly 5, which is made by combining the mounting table 10 and the edge ring 30, becomes uniform, or temperature controllability of the mounting table assembly 5 is improved. The temperature difference (temperature distribution) of the edge ring 30 may preferably be approximately 1° C. in the circumferential direction of the edge ring 30, and more preferably be approximately 0.5° C.

### [Edge Ring Configuration]

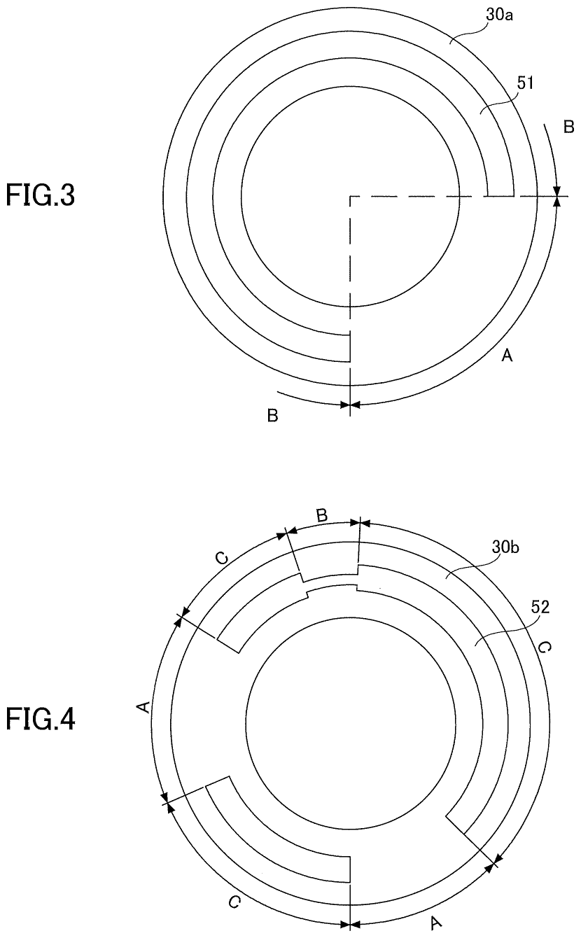

The edge ring 30 according to the present embodiment includes, in a part of the edge ring 30, a portion having different thermal conductivity from a material forming the edge ring 30. The portion extends in a circumferential direction of the part of the edge ring 30. Hereinafter, as an example of the above-described portion, a groove 51 extending in the circumferential direction of an edge ring 30a is described. FIG. 3 is a back view of an edge ring 30a according to the present embodiment. In the edge ring 30a according to the present embodiment, the groove 51 is formed on a surface of the edge ring 30a that touches the electrostatic chuck 25. The groove 51 is provided in a part, having a shape of a sector (annulus sector), in the back surface of the edge ring 30a of the edge ring 30a. In the example of FIG. 2, the groove 51 is not provided in a sector of a region A. The groove 51 is formed in a sector of a region B. The size of the region A and the size of the region B differ. The depth of the groove 51 is adjusted appropriately so that temperature distribution is uniform. The groove 51 is a space made by changing a height of the back surface of the edge ring 30a. Similarly, the groove, a hole, a step, and the like, which will be described below in variations of the present embodiment, are spaces made by changing the height of the back surface of the edge ring.

### [Location of Groove]

The relationship between heat transfer between the edge ring 30 and the electrostatic chuck 25 and the location of the groove will be described with reference to FIG. 2. FIG. 2 illustrates a cross-sectional view of the edge ring 30a in the region A and in the region B.

A back surface of the edge ring 30a in the region A is flat. That is, no grooves are formed on the back surface of the edge ring 30a in the region A. In contrast, in the region B of the edge ring 30a, a single arcuate groove 51 is formed circumferentially on the back surface of the edge ring 30a. From the plasma P, heat H1 enters the upper surface 30a1 of the edge ring 30a. After the heat H1 enters the edge ring 30a part of the heat H1, which is denoted by “H2” in FIG. 2, passes through the edge ring 30a, and flows out from the back surface 30a2 of the edge ring 30a. The size of the member forming the back surface 30a2 in the region B of the edge ring 30a per unit area of the region B that contacts the mounting surface 25b1 of the electrostatic chuck 25 is smaller than the size of the member forming the back surface 30a2 in the region A of the edge ring 30a per unit area of the region A that contacts the mounting surface 25b1 of the electrostatic chuck 25. Therefore, when heat transfer efficiency of the edge ring 30a with respect to the mounting surface 25b1 is compared between the region A and the region B, the heat transfer efficiency in the region B is lower than the heat transfer efficiency in the region A. Accordingly, in the region B, the amount of heat H2 per unit area released from the back surface 30a2 is lower than the amount of heat H2 per unit area released from the back surface 30a2 in the region A. Therefore, in the region B, heat H1 from the plasma P is more difficult to be released as compared to the region A, and a higher temperature region RH is generated in the region B, in which a temperature of the upper surface 30a1 is higher than a temperature of the upper surface 30a1 in the region A.

As described above, the edge ring 30a includes a region (region A) in which the groove 51 in the circumferential direction is not provided, and a region (region B) in which the groove 51 in the circumferential direction is provided. The regions A and B differ in an amount of the heat H2 per unit area removed from the back surface 30a2 of the edge ring 30a. Therefore, the upper surface 30a1 of the edge ring 30a tends to have a higher temperature in the region B than in the region A. As described above, the edge ring 30a has a region in which the groove 51 is provided in the circumferential direction and a region in which the groove 51 is not provided, so that temperature distribution is generated on the upper surface 30a1 of the edge ring 30a, which is a surface on the side facing the plasma P. Suppose that the temperature in the region B becomes relatively lower than the temperature in the region A if the edge ring 300 of the comparative example, whose surface facing the mounting surface 25b1 is flat, is used. In this case, if the edge ring 30a, in which the groove 51 is provided on the surface of the edge ring 30a in the region B, is employed in the mounting table assembly 5 according to the present embodiment, the edge ring 30a can increase the temperature at the region B of the edge ring 30a because heat transfer efficiency between the edge ring 30a and the electrostatic chuck 25 is degraded in the region B. This allows the temperature of the entire edge ring 30a to be uniform.

### Effect

As described above, the mounting table assembly 5 according to the present embodiment includes the edge ring 30 whose back surface facing the mounting surface of the mounting table 10 is provided with the groove 51 in a part of the back surface in the circumferential direction. The groove 51 is an example of a portion of the edge ring 30 whose thermal conductivity differs from that of a material (such as silicon) forming the edge ring 30. The portion is provided in an area corresponding to an annulus sector of the edge ring 30. This allows the temperature distribution of the edge ring 30a to be uniform during plasma processing. This can also form a higher temperature region and a lower temperature region in the edge ring 30a during plasma processing.

Further, for example, by providing the groove 51 on the back surface of the edge ring 30 in an area corresponding to a sector of an edge region of the substrate W in which deviation of critical dimension (CD) or deviation of an etch rate needs to be adjusted, or by providing the groove 51 on the back surface of the edge ring 30 in an area not corresponding to a sector of an edge region of the substrate W in which deviation of the CD or deviation of an etch rate needs to be adjusted, deviation of the CD or the etch rate can be corrected. This eliminates a need to use other parts used to control the temperature of the substrate, and therefore deviation of the CD or the like can be adjusted at low cost, without increasing installation effort such as centering of the edge ring 30.

### <Variations>

### [First Variation of Edge Ring]

FIG. 4 is a diagram illustrating a back surface of an edge ring 30b, which is an example of a first modification of the edge ring 30a according to the present embodiment.

In a part of the back surface of the edge ring 30b in the circumferential direction, a groove 52, which is an example of a portion having different thermal conductivity from a material forming the edge ring 30b, is provided. Width of the groove 52 in the radial direction varies depending on the location. This allows temperature distribution in the circumferential direction to be adjusted more finely. For example, suppose that the temperature in a region A in FIG. 4 is highest, the temperature in a region B is lower than the region A, and the temperature in a region C is lower than the region B, if the edge ring 300 of the comparative example, whose surface facing the mounting surface 25b1 is flat, is employed. In this case, the edge ring 30b may be configured such that a groove is not formed in the region A, and that a groove is formed in the regions B and C. Accordingly, heat transfer efficiency in the regions B and C between the edge ring 30b and the electrostatic chuck 25 is lower than in the region A. Further, the width of the groove 52 of the edge ring 30b in the radial direction is wider in the region C than in the region B. Thus, heat transfer efficiency between the edge ring 30b and the electrostatic chuck 25 is different between the regions B and C in which the groove 52 is formed. That is, heat transfer efficiency between the edge ring 30b and the electrostatic chuck 25 is lower in the region C than in the region B. In this manner, finer temperature adjustments can be made. Accordingly, uniformity in temperature distribution of the edge ring 30b can be improved.

### [Second Variation of Edge Ring]

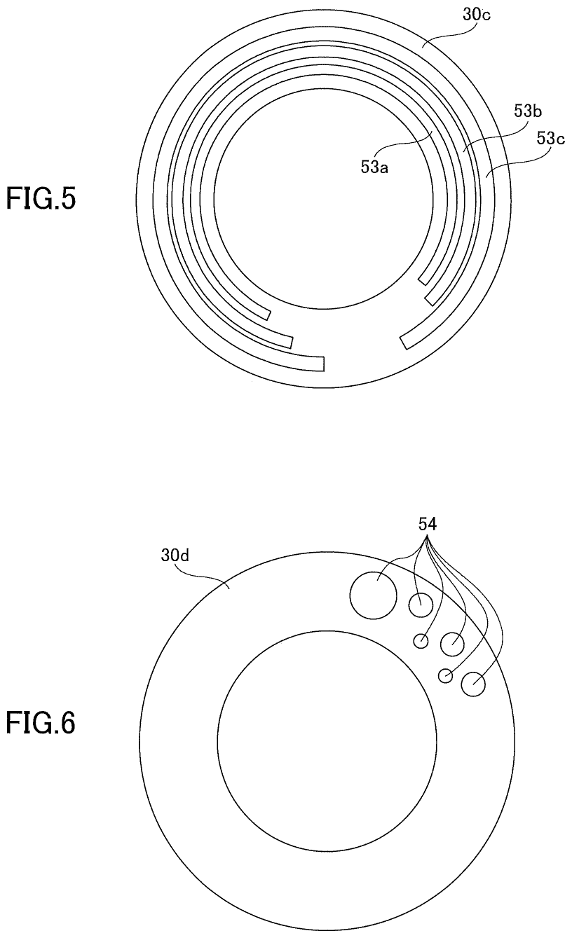

FIG. 5 is a diagram illustrating a back surface of an edge ring 30c, which is an example of a second variation of the edge ring 30a according to the present embodiment.

The edge ring 30c includes multiple grooves 53 (53a, 53b, and 53c) in a part of the edge ring 30c in the circumferential direction of the edge ring 30c. The grooves 53a, 53b, and 53c are each an example of a portion of the edge ring 30c whose thermal conductivity is different from that of a material forming the edge ring 30c, and each of the grooves 53a, 53b, and 53c is disposed at a different position in a radial direction of the edge ring 30c. Because the multiple grooves 53 are provided in the edge ring 30c in its radial direction, that is, because the multiple portions whose thermal conductivity is different from that of a material forming the edge ring 30c are provided in the radial direction of the edge ring 30c, in an area corresponding to an annulus sector of the edge ring 30c, temperature distribution in the radial direction can be made to be more uniform. Further, by adjusting the lengths of the grooves 53 (53a, 53b, and 53c), temperature distribution in the circumferential direction can be made to be more uniform. Accordingly, uniformity of the temperature distribution of the edge ring 30c can be improved.

### [Third Variation of Edge Ring]

FIG. 6 is a diagram illustrating a back surface of an edge ring 30d, which is an example of a third variation of the edge ring 30a according to the present embodiment.

The edge ring 30d includes multiple circular holes 54 instead of a groove, in a part of the edge ring 30d. Each of the holes 54 is an example of a portion of the circumferential portion of the edge ring 30d whose thermal conductivity is different from that of a material forming the edge ring 30d. By varying diameters of the hole 54 and the number of the hole 54 in accordance with a location in the edge ring 30d, heat transfer efficiency between the edge ring 30d and the electrostatic chuck 25 can be changed. This allows temperature distribution of the edge ring 30d to be uniform. The shape of the hole 54 in the top view is not limited to a circle as illustrated in FIG. 6. For example, the shape of the hole 54 may be a polygon such as a triangle or a square, or may be an ellipse.

### [Fourth Variation of Edge Ring]

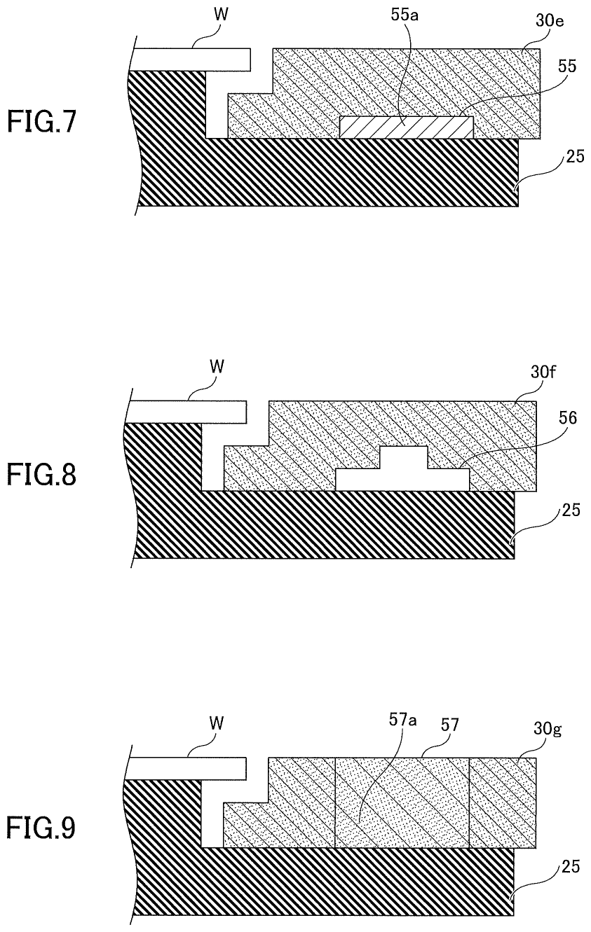

FIG. 7 is a cross-sectional view of an edge ring 30e, which is a fourth variation of the edge ring 30a according to the present embodiment.

The edge ring 30e includes a groove 55 in a part of the edge ring 30e in the circumferential direction of the edge ring 30e. The groove 55 is an example of a portion whose thermal conductivity is different from that of a material forming the edge ring 30e. Also, a filler 55a is embedded in the groove 55. The filler 55a may be gas, liquid, or solid. As the filler 55a, a material having thermal conductivity lower than the thermal conductivity of the material forming the edge ring 30e is used. By using the filler 55a whose thermal conductivity is different from that of the member of the edge ring 30e, heat transfer efficiency between the edge ring 30e and the electrostatic chuck 25 can be changed. Thus, uniformity in temperature distribution of the edge ring 30e can be improved.

### [Fifth Variation of Edge Ring]

FIG. 8 is a cross-sectional view of an edge ring 30f, which is an example of a fifth variation of the edge ring 30a according to the present embodiment.

The edge ring 30f includes a stepped groove 56 (i.e., a groove having a step), in a part of the edge ring 30f in the circumferential direction of the edge ring 30e. The stepped groove 56 is an example of a portion whose thermal conductivity is different from that of a material forming the edge ring 30f. The stepped groove 56 has a step such that a depth of the stepped groove 56 is not uniform in a radial direction of the edge ring 30f. By changing the depth of the groove in the radial direction, the temperature distribution in the radial direction can be adjusted more finely. Therefore, uniformity of the temperature distribution of the edge ring 30f can be improved.

### [Sixth Variation of Edge Ring]

FIG. 9 is a cross-sectional view of an edge ring 30g, which is an example of a sixth variation of the edge ring 30a according to the present embodiment.

The edge ring 30g includes a through groove 57 in a part of the edge ring 30g in the circumferential direction of the edge ring 30g. The through groove 57 is an example of a portion whose thermal conductivity is different from that of a material forming the edge ring 30g. In the sixth variation, part of the groove 51 of the edge ring 30a is the through groove 57. Also, a filler 57a is embedded in the through groove 57. By employing, as a material of the filler 57a, a material having different thermal conductivity from the material of the edge ring 30g, heat transfer efficiency between the edge ring 30g and the electrostatic chuck 25 can be changed. Thus, uniformity in temperature distribution of the edge ring 30g can be improved.

### [Seventh Variation of Edge Ring]

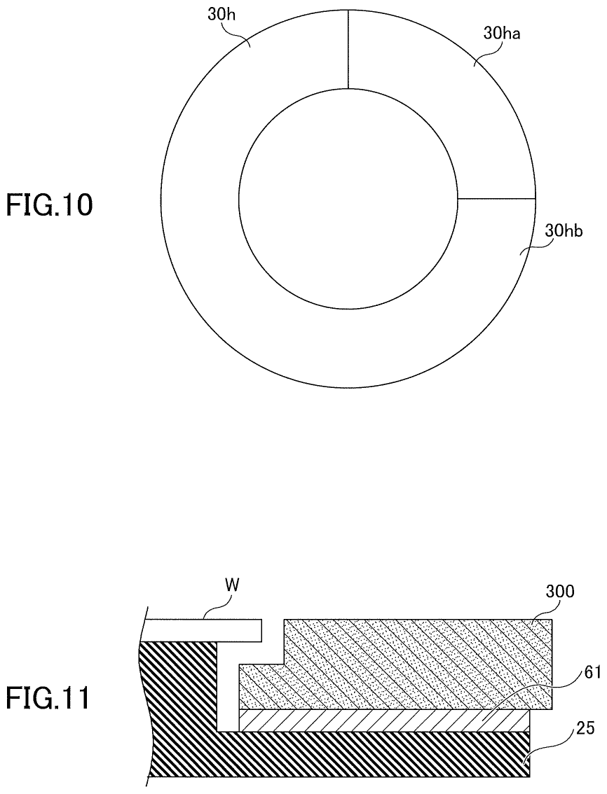

FIG. 10 is a diagram illustrating a back surface of an edge ring 30h, which is an example of a seventh variation of the edge ring 30a according to the present embodiment.

As illustrated in FIG. 10, the edge ring 30h is composed of a first member 30ha having a shape of an annulus sector and a second member 30hb having a shape of an annulus sector. In the following description, the first member 30ha may also be referred to as an edge ring 30ha, and the second member 30hb may also be referred to as an edge ring 30hb. The edge ring 30ha and the edge ring 30hb are formed of materials having different thermal conductivity from each other. For example, the edge ring 30ha may be formed of silicon carbide SiC, and the edge ring 30hb may be formed of silicon Si. This allows heat transfer efficiency between the edge ring 30g and the electrostatic chuck 25 to be changed. For example, the edge ring 30hb is an example of a portion of the edge ring 30h in the circumferential direction whose thermal conductivity differs from that of a material forming the edge ring 30h. Therefore, uniformity in temperature distribution of the edge ring 30h can be improved.

### [First Variation of Mounting Table Assembly]

In the above-described embodiment and its variations, as an example of a portion whose thermal conductivity is different from that of a material forming the edge ring 30, a groove or the like is provided in a part of the back surface of the edge ring 30 that faces the mounting surface of the mounting table, but a portion having different thermal conductivity may be provided in other members than the edge ring 30. In the following, a first variation of the mounting table assembly will be described, in which a portion having different thermal conductivity is provided in a sheet member.

FIG. 11 is a cross-sectional view illustrating an example of a mounting table assembly according to a first variation of the present embodiment. In the mounting table assembly of FIG. 11, a sheet member 61 that transfers heat is provided between the edge ring 300 and the electrostatic chuck 25. Multiple sheet members 61 having different thermal conductivities may be provided between the edge ring 300 and the electrostatic chuck 25. For example, a first sheet member 61 having high thermal conductivity may be provided in a region in which the temperature of the edge ring is desired to be lowered, and a second sheet member 61 having low thermal conductivity may be provided in a region in which the temperature of the edge ring is desired to be raised. This allows heat transfer efficiency between the edge ring 300 and the electrostatic chuck 25 to be changed. As described above, the sheet member may be formed such that a portion having different thermal conductivity from the other portions of the sheet member is provided at a location determined in accordance with temperature distribution of the edge ring 300 during plasma processing. This can improve uniformity in temperature distribution of the edge ring.

In addition, a groove or a hole may be provided in the sheet member to reduce thermal conductivity of the sheet member. Also, a sheet member may be provided only in a part in the circumferential direction, e.g., a region in which the temperature of the edge ring is desired to be lowered. In addition, use of a sheet member may be combined with an edge ring having a groove.

### [Second Variation of Mounting Table Assembly]

Next, as a second variation of the mounting table assembly, a case in which a portion having different thermal conductivity is provided in the electrostatic chuck will be described. FIG. 12 is a cross-sectional view illustrating an example of a mounting table assembly according to the second variation of the present embodiment. In the second variation of FIG. 12, a groove 70 is provided on the electrostatic chuck 25d in a portion corresponding to the groove 51 of the edge ring 300 in the present embodiment. This allows heat transfer efficiency between the edge ring 300 and the electrostatic chuck 25d to be changed. Also, uniformity in temperature distribution of the edge ring can be improved. The second variation may be employed in combination with at least one of the edge ring having the groove and the sheet member.

The mounting table, the substrate processing apparatus, and the edge ring according to the present embodiment and its variations that have been disclosed herein should be considered exemplary in all respects and not limiting. The above embodiment and its variations may be modified and enhanced in various forms without departing from the appended claims and spirit thereof. Matters described in the above embodiment and its variations may take other configurations to an extent not inconsistent, and may be combined to an extent not inconsistent.

The substrate processing apparatus of the present disclosure is applicable to any of the following types of processing apparatuses: a capacitively coupled plasma (CCP) type processing apparatus, an inductively coupled plasma (ICP) type processing apparatus, a processing apparatus using a radial line slot antenna (RLSA), an electron cyclotron resonance plasma (ECR) type processing apparatus, and a helicon wave plasma (HWP) type processing apparatus.

What is claimed is:

1. A substrate support assembly comprising:
an edge ring,
a substrate support having a central portion that supports a substrate, and an outer peripheral portion that supports the edge ring arranged around the substrate; and
a thermal conductivity adjuster that is in contact with a part of the edge ring in a circumferential direction, the thermal conductivity adjuster having a thermal conductivity different from a thermal conductivity of the edge ring.

2. The substrate support assembly according to claim 1, wherein in the substrate support assembly, a size of an area having the thermal conductivity adjuster is different from a size of an area not having the thermal conductivity adjuster.

3. The substrate support assembly according to claim 1, wherein
at least one of a back surface of the edge ring and an upper surface of the outer peripheral portion includes a recess; and
the thermal conductivity adjuster is configured by a space defined by the recess.

4. The substrate support assembly according to claim 3, wherein the recess is a groove or a step provided on the back surface of the edge ring or on the upper surface of the outer peripheral portion.

5. The substrate support assembly according to claim 1, wherein
at least one of a back surface of the edge ring and an upper surface of the outer peripheral portion includes a recess; and
the thermal conductivity adjuster is configured by a material that is filled in the recess, the material having a thermal conductivity different from the thermal conductivity of the edge ring.

6. The substrate support assembly according to claim 1, wherein the thermal conductivity adjuster is provided as a plurality of thermal conductivity adjusters arranged in a radial direction.

7. The substrate support assembly according to claim 1, wherein the thermal conductivity adjuster is disposed in accordance with a temperature distribution over the edge ring during plasma processing.

8. The substrate support assembly according to claim 1, wherein the thermal conductivity adjuster is provided in the part of the edge ring in the circumferential direction.

9. The substrate support assembly according to claim 1, wherein the thermal conductivity adjuster is configured by a sheet disposed between a back surface of the edge ring and an upper surface of the outer peripheral portion.

10. The substrate support assembly according to claim 1, further comprising a sheet provided between a back surface of the edge ring and an upper surface of the outer peripheral portion.

11. The substrate support assembly according to claim 1, further comprising a plurality of sheets provided between a back surface of the edge ring and an upper surface of the outer peripheral portion, each of the plurality of sheets having a different thermal conductivity.

12. The substrate support assembly according to claim 1, further comprising a sheet provided between a back surface of the edge ring and an upper surface of the outer peripheral portion, wherein the sheet is disposed at a position in accordance with a temperature distribution of the edge ring during plasma processing.

13. The substrate support assembly according to claim 1, further comprising a sheet provided at location corresponding to the part of the edge ring in the circumferential direction, between a back surface of the edge ring and an upper surface of the outer peripheral portion.

14. A substrate processing apparatus comprising the substrate support assembly according to claim 1.

15. An edge ring provided on a substrate support on which a substrate to be plasma processed is placed, wherein
the edge ring is disposed on the substrate support so as to surround the substrate,
a back surface of the edge ring faces an upper surface of the substrate support, and
a recess is formed on a part of the back surface of the edge ring in a circumferential direction.
